(19) United States
(12) Patent Application Publication
(10) Pub. No.: US 2007/0164236 A1
(43) Pub. Date: Jul. 19, 2007

(54) Method for retrieving signal from circuit

(76) Inventors: Wei-Been Yu, Hsin Chu City (TW); Yung-Shun Liao, Erlun Township (TW); Hsin-Sheng Liao, Lunbei Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/319,628

(22) Filed: Dec. 29, 2005

(51) Int. Cl. H01J 37/08

(52) U.S. Cl. 250/492.21

(57) ABSTRACT

The present invention relates to a method for retrieving a signal from a circuit within a substrate. The method comprising steps of: (a) selecting at least one from the plurality of electrodes for signal retrieving; (b) removing materials covering said selected electrode with a focused ion beam (FIB) or a laser to form contact hole for exposing said selected electrode; (c) depositing in said contact hole a conductive material for forming electrically conductive pier by applying said focused ion beam (FIB) or a laser over gas molecules; (d) disposing an electrically conductive viscid material over each electrically conductive pier; and (e) connecting the electrically conductive viscid material with a conductive wire. Thus, the signal could be retrieved from the electrically conductive wire.

### BACKGROUND OF THE INVENTION

1. Field of the Invention

The present invention relates to a method for retrieving a signal from a circuit within a substrate, and more particularly, to a method for retrieving a signal from an existing integrated circuit including at least one electrode.

2. Related Prior Arts

FIGS. 13˜16 illustrate the conventional processes for modifying an integrated circuit. First, a layered structure (74) formed on the selected electrode (73) is removed by shooting the focused ion beam FIB (72) or the laser beam in order to form a contact hole (75), where the electrode (73) is exposed. The layered structure (74) generally includes conductive layers, semi-conductive layers, and insulation layers, etc., and is formed during the semiconductor manufacturing processes. Then a nozzle (721) ejects gas molecules with focused ion beam into the contact hole (75), which is further deposited a conductive material to form electrically conductive piers (76). Alternatively, as shown in FIGS. 15 and 16, the insulation film (77) is deposited first on the inner wall of each contact hole (75), and afterwards the electrically conductive pier (76) is formed over the insulation films (77) by the deposition of a conductive material. At last, the conductive piers (76) are adapted to connect with each other via the conductive bridge floor (78) which is formed by depositing the same conductive material as the piers. Though applying the above processes can change connections between the electrodes of the integrated circuit, it's still impossible inserting an additional device to the integrated circuit. Therefore, the need of modifying the integrated circuits remains unsatisfied.

### SUMMARY OF THE INVENTION

The present invention provides a method for retrieving a signal from a circuit within a substrate. The method comprising steps of: (a) selecting at least one from the plurality of electrodes for signal retrieving; (b) removing materials covering said selected electrode with a focused ion beam (FIB) or a laser to form contact hole for exposing said selected electrode; (c) depositing in said contact hole a conductive material for forming electrically conductive pier by applying said focused ion beam (FIB) or a laser with gas molecules ejected from a nozzle; (d) disposing an electrically conductive viscid material over each electrically conductive pier; and (e) connecting the electrically conductive viscid material with a conductive wire. Then the signal can be retrieved from the electrically conductive wire.

The present invention also provides a method for retrieving a signal from a circuit within a substrate, and transmits the signal from the selected electrode via the conductive wire for testing or modification by inserting an additional electronic element.

The present invention provides a novel method for retrieving a signal from a circuit within a substrate, and transmits the signal to an additional device or a testing system via an electrically conductive viscid material and a conductive wire, so that the circuit can be modified or detected easily. Thus the samples of the product, which are created with lower cost but better quality, can be delivered to the clients in appropriate time.

### BRIEF DESCRIPTION OF THE DRAWINGS

FIG. 1 is a cross section view of the substrate on which the contact hole is formed with the focused ion beam (FIB) according to one embodiment of the present invention.

FIG. 2 is a cross section view of the electrically conductive pier, which is made from gas molecules ejected from the nozzle of the FIB according to the embodiment of the present invention.

FIG. 3 is a cross section view of the electrically conductive viscid material, which is placed on the electrically conductive pier and adapted to connect with a conductive wire according to the embodiment of the present invention.

FIG. 4 is a cross section view of the electrically conductive viscid material, which is covered with an insulation material according to another embodiment of the present invention.

FIG. 5 shows the conductive wire adapted to connect with a measurement system according to another embodiment of the present invention.

FIG. 6 shows the conductive wire adapted to connect with an electrode formed on another substrate according to another embodiment of the present invention.

FIG, 7 shows the conductive wire adapted to connect with a metal pad of the integrated circuit according to another embodiment of the present invention.

FIG. 8 shows the conductive wire adapted to connect with an electronic element according to another embodiment of the present invention.

FIG. 9 shows the conductive wire adapted to connect with a metal pad of a circuit board according to another embodiment of the present invention.

FIG. 10 shows the conductive wire adapted to connect with another conductive wire according to another embodiment of the present invention.

FIG. 11 is a cross section view of the electrically conductive viscid material being placed on the lateral segments of the electrically conductive piers and adapted to connect with a conductive wire according to another embodiment of the present invention.

FIG. 12 is a cross section view of the electrically conductive viscid material, which is covered with an insulation material on the lateral segments of the electrically conductive piers according to another embodiment of the present invention.

FIG. 13 is a cross section view of the substrate on which the contact hole is formed by the FIB according to the conventional process.

FIGS. 14˜16 are cross section: views of a floor of the electrically conductive bridge which is made from gas molecules ejected from a nozzle of the FIB according to the conventional process.

### DETAILED DESCRIPTION OF THE PREFERRED EMBODIMENTS

Though the method of the present invention can be applied to many fields, preferred embodiments are illustrated herewith. People skilled in the art can understand other embodiments according to the present invention.

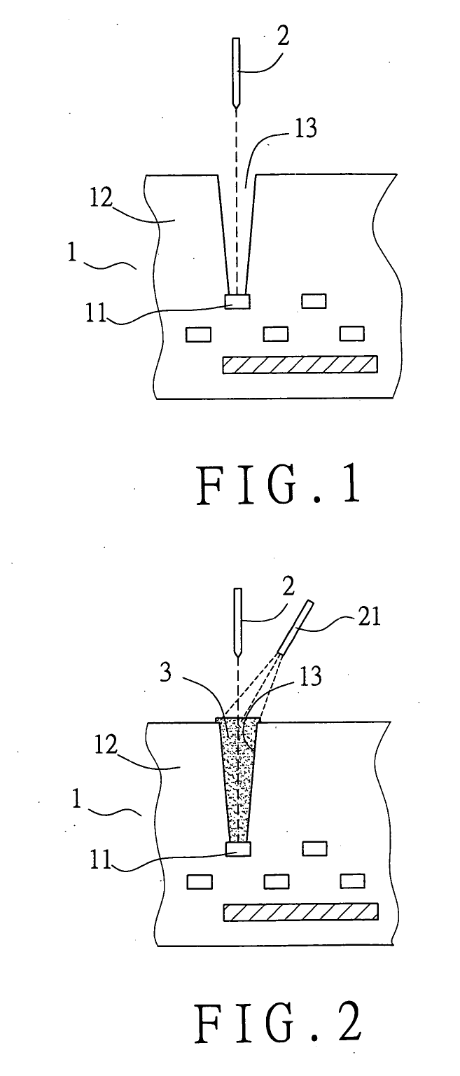

Referring to the embodiment described in FIG. 1, a substrate (1), such as an integrated circuit, includes a plurality of electrodes (11). At least one electrode is selected for retrieving a signal therefrom. A layered structure (12) covering the selected electrode (11) is removed by a focused ion beam (FIB) (2) or a laser beam, to form a contact hole (13) and to expose the electrode (11). The layered structure (12) generally comprises conductive layers, semiconductive layers, and insulation layers. The layered structure (12) is formed during the semiconductor manufacturing processes.

Then gas molecules, ejected from a nozzle (21) of the FIB (2) or the laser beam, are deposited in the contact hole (13) to form an electrically conductive pier (3), as shown in FIG. 2. Alternatively, an insulation film (not shown in figures) can be previously formed over an inner wall of the contact hole (13), and then the electrically conductive pier (3) is deposited on the insulation film.

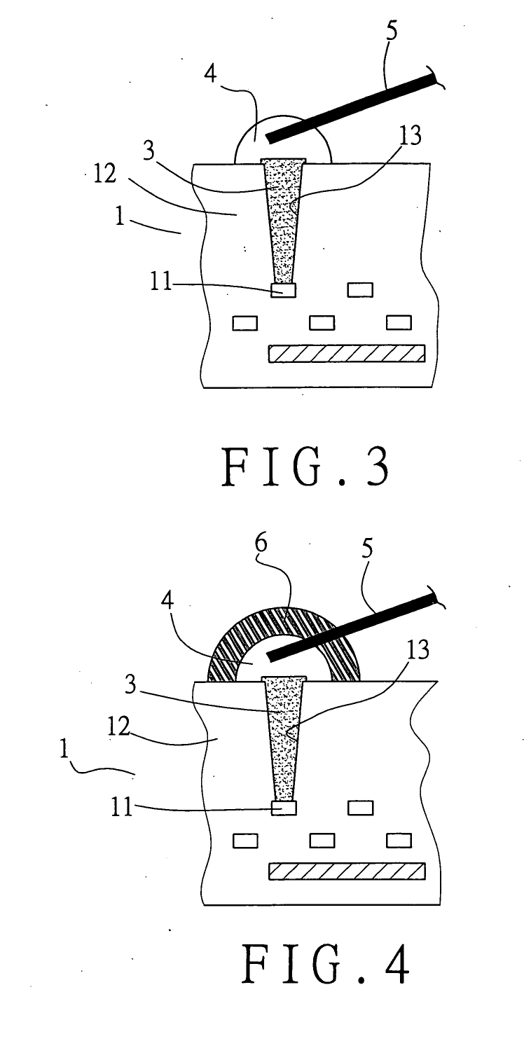

Referring to the embodiment described in FIG. 3, an electrically conductive viscid material (4) such as a conductive adhesive or a conductive glue, is placed over the electrically conductive pier (3) and further associated with a conductive wire (5) to form an electrically conductive path. Accordingly, the signal can be introduced/probed from the selected electrodes (11).

Referring to the embodiment described in FIG. 4, the electrically conductive viscid material (4) placed on the electrically conductive pier (3) and adapted to connect with the conductive wire (5) can be covered with an insulation material (6) such as insulation glue or an insulation adhesive etc., so that connection between the electrically conductive viscid material (4) and the conductive wire (5) can be strengthened or reinforced.

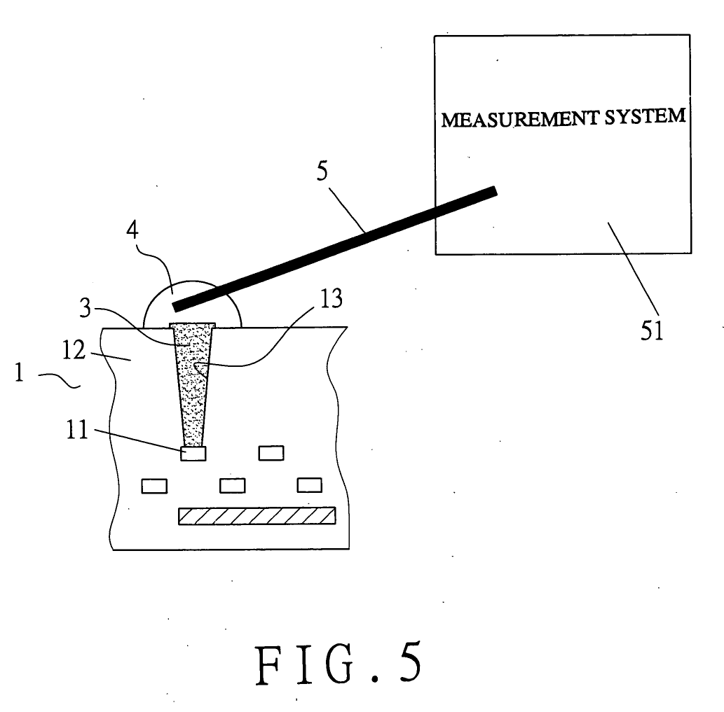

Referring to the embodiment described in FIG. 5, the electrode (11) of the substrate (1) can be adapted to connect with a measurement system (51) via the electrically conductive pier (3), the electrically conductive viscid material (4) and the conductive wire (5).

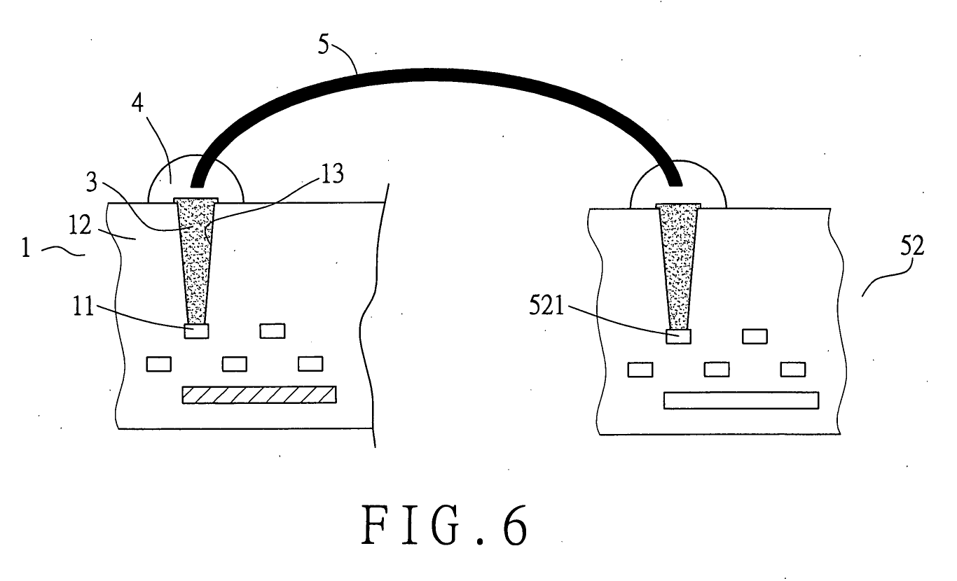

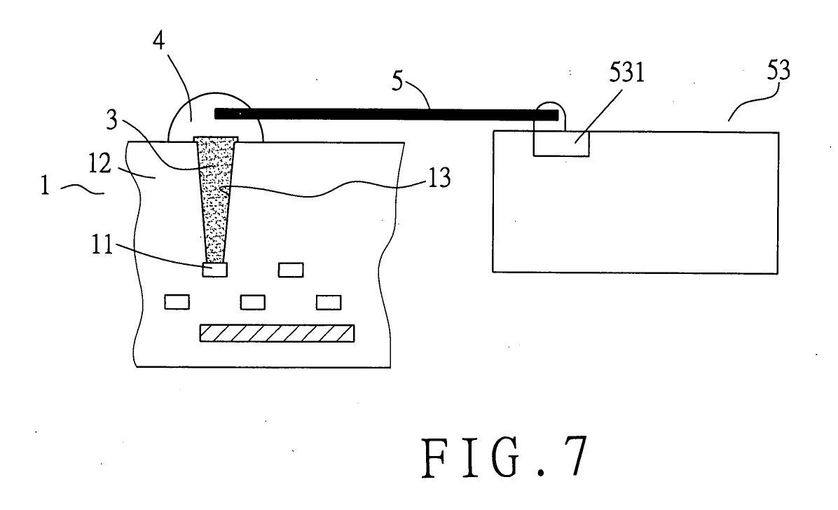

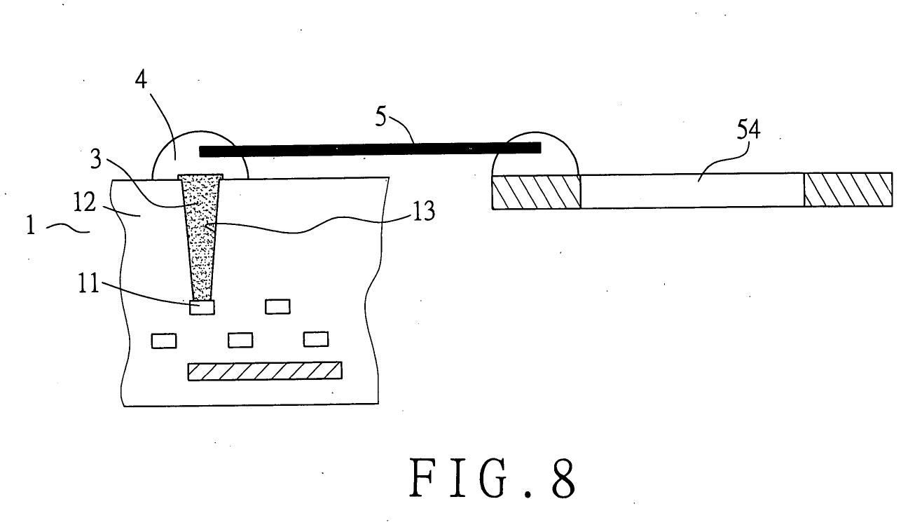

Referring to the embodiment described in FIG. 6, it illustrates the conductive wire (5) adapted to connect with an electrode (521) formed on another substrate (52).

Referring to the embodiment described in FIG. 7, it illustrates the conductive wire (5) adapted to connect with a metal pad (531), for example, of another integrated circuit (53).

Referring to the embodiment described in FIG. 8, it illustrates the conductive wire (5) adapted to connect with an additional electronic element (54).

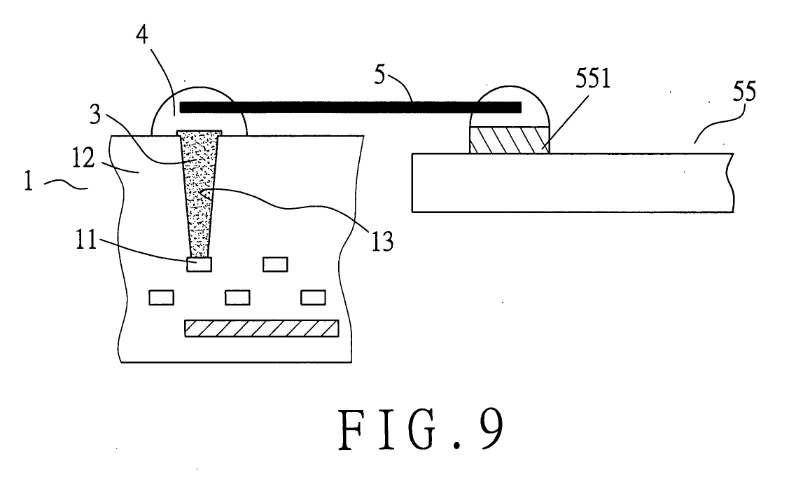

Referring to the embodiment described in FIG. 9, it illustrates the conductive wire (5) adapted to connect with a metal pad (551), for example, of a circuit board (55).

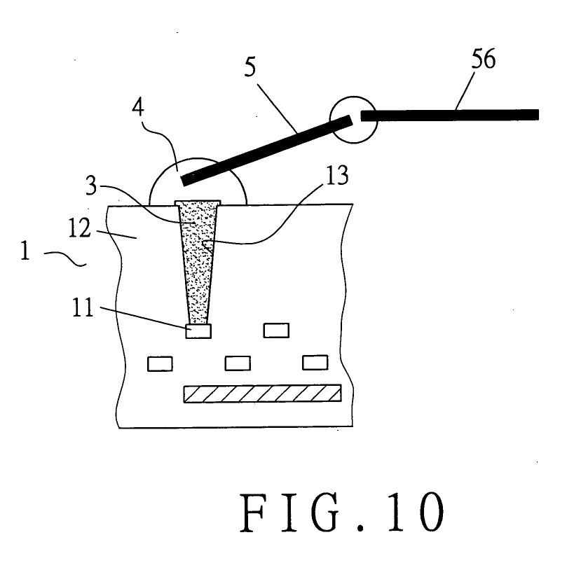

Referring to the embodiment described in FIG. 10, it illustrates the conductive wire (5) adapted to connect with another conductive wire (56), so that the signal of the electrode (11) can be retrieved via the conductive wires (5) for detection or modification purposes.

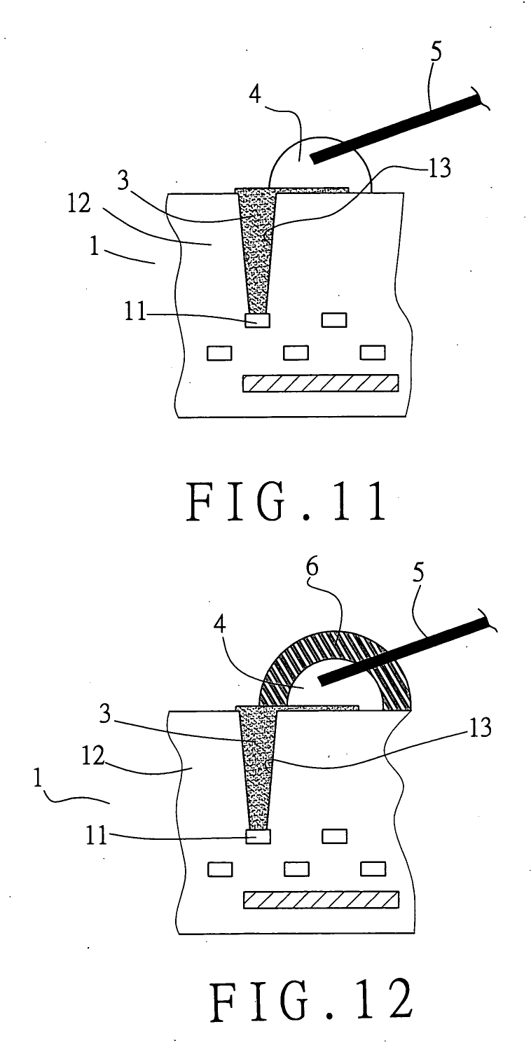

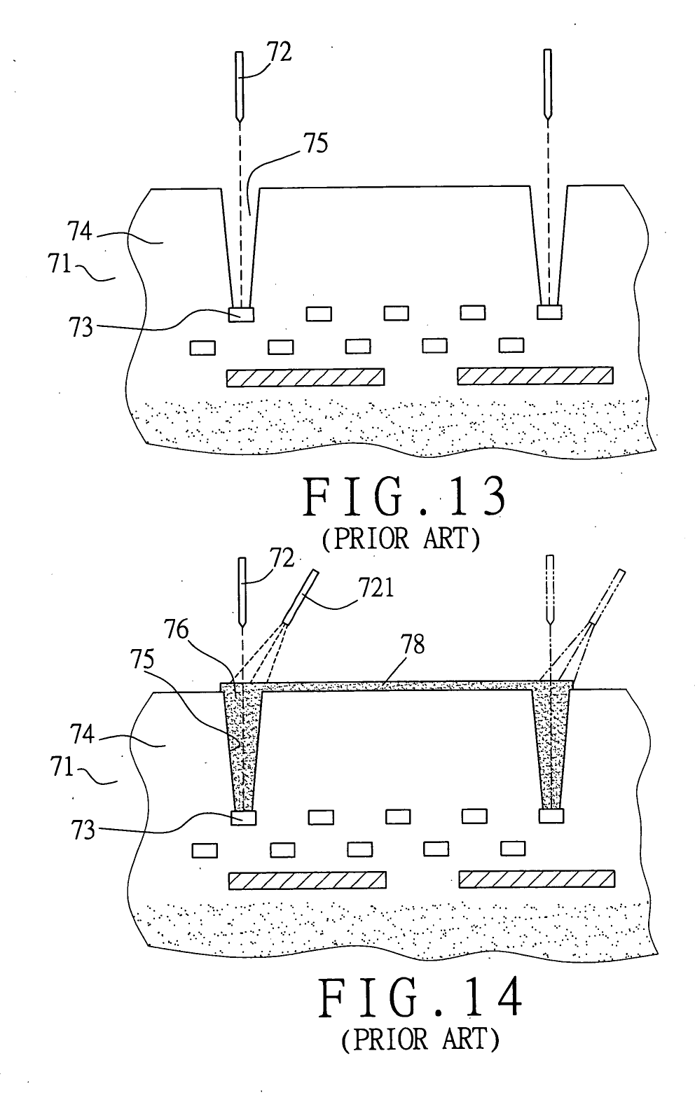

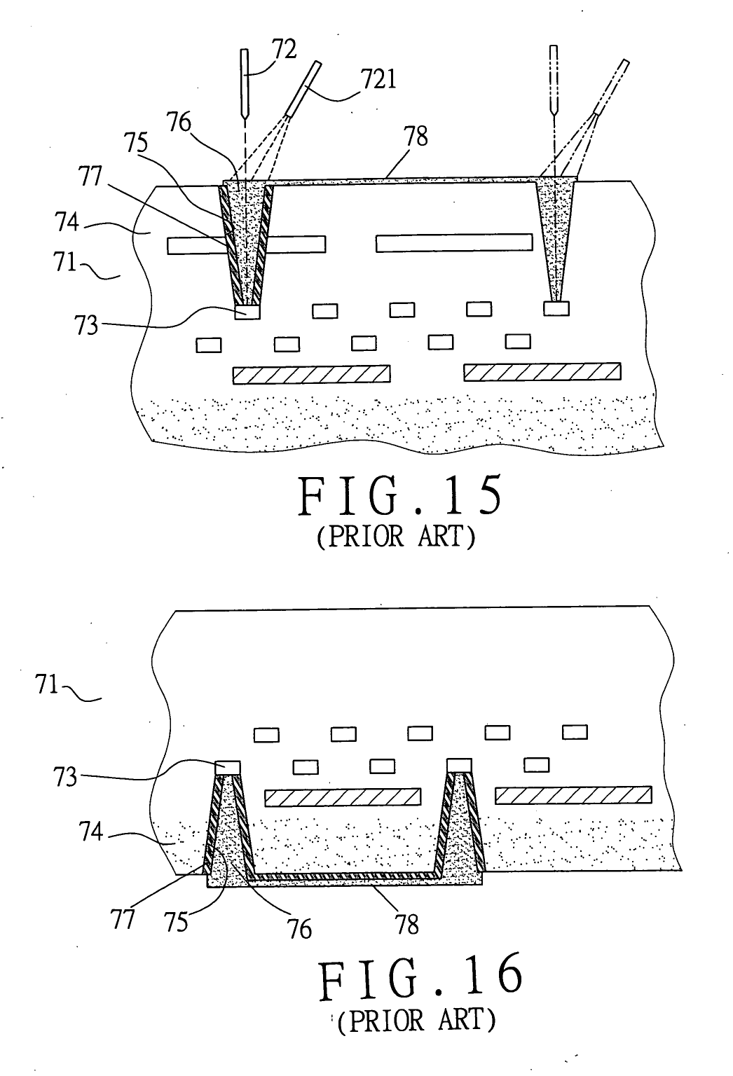

Further referring to the embodiment described in FIG. 11, it illustrates a lateral segment (31) formed on the top edge thereof and over the layered structure (12).

Referring to the embodiment described in FIG. 12, the lateral segments (31) are also made from the same material as the electrically conductive piers (3) and can be adapted to connect with the conductive wire (5) by means of the electrically conductive viscid material (4) to form an electrically conductive path. Besides, the electrically conductive viscid material (4) can be covered by an insulation material (6), for the purposes of retrieving signals from the selected electrodes (11).

Accordingly, the electrically conductive pier and the electrically conductive viscid material formed on the substrate with the FIB or the laser beam can be used to retrieve signals from the electrode via the conductive wires for detection or circuit modification. Such effects couldn't be achieved when applying the conventional method.

It should be noted that the above is merely to illustrate the preferred embodiment of the present invention, but not limited to the scope thereof. Other embodiments may be devised without departing from the spirit of the inventions and the scope of the appended claims.

What is claimed is:

1. A method for retrieving a signal from a circuit within a substrate, the method comprising steps of:
(a) selecting at least one from the plurality of electrodes for signal retrieving;
(b) removing materials covering said selected electrode with a focused ion beam (FIB) to form contact hole for exposing said selected electrode;
(c) depositing in said contact hole a conductive material for forming electrically conductive pier by applying said focused ion beam (FIB) with a gas molecule ejected from a nozzle;
(d) disposing an electrically conductive viscid material over each electrically conductive pier; and
(e) connecting the electrically conductive viscid material with a conductive wire;
wherein the signal is retrieved from the electrically conductive wire.

2. The method of claim 1, wherein said the circuit is in form of integrated circuit (IC).

3. The method of claim 1, wherein said the circuit is in form of printed circuit board (PCB).

4. The method of claim 1, further comprising a following step between the step (b) and (c):
(b-1) forming insulation film over an inner wall of each contact hole.

5. The method of claim 1, wherein said electrically conductive viscid material is a conductive adhesive.

6. The method of claim 1, wherein said electrically conductive viscid material is a conductive glue.

7. The method of claim 1, further comprising the step of: (f) forming an insulation layer over the conductive viscid material.

8. The method of claim 1, wherein said conductive wire is connected to a testing system.

9. The method of claim 1, wherein said conductive wire is adapted to connected with an electrode of a circuit within another substrate.

10. The method of claim 1, wherein said conductive wire is adapted to connect with an electronic element.

11. The method of claim 1, wherein said conductive wire is adapted to connect with a pad of an integrated circuit.

12. The method of claim 1, wherein said conductive wire is adapted to connect with a pad on a circuit board.

13. The method of claim 1, wherein said conductive wire is adapted to connect with another conductive wire.

14. The method of claim 1, wherein said electrically conductive pier comprises a lateral segment of the same material at the top edge of the conductive pier.

15. A method for retrieving a signal from a circuit within a substrate, the method comprising steps of:
(a) selecting at least one from the plurality of electrodes for signal retrieving;
(b) removing materials covering said selected electrode with a laser to form contact hole for exposing said selected electrode;
(c) depositing in said contact hole a conductive material for forming electrically conductive pier by applying said laser with a gas molecule ejected from a nozzle;
(d) disposing an electrically conductive viscid material over each electrically conductive pier; and
(e) connecting the electrically conductive viscid material with a conductive wire;
wherein the signal is retrieved from the electrically conductive wire.

16. The method of claim 15, wherein said the circuit is in form of integrated circuit (IC).

17. The method of claim 15, wherein said the circuit is in form of printed circuit board (PCB).

18. The method of claim 15, further comprising a following step between the step (b) and (c):
(b-1) forming insulation film over an inner wall of each contact hole.

19. The method of claim 15, wherein said electrically conductive viscid material is a conductive adhesive.

20. The method of claim 15, wherein said electrically conductive viscid material is a conductive glue.
